(19) United States
(12) Patent Application Publication
(10) Pub. No.: US 2009/0233225 A1
(43) Pub. Date: Sep. 17, 2009

(54) Low chlorine epoxy resin formulations

(76) Inventors: Donald W. Johnson, Wayland, MA (US); Wen Dai, Ashland, MA (US)

Correspondence Address: WIGGIN AND DANA LLP;ATTENTION: PATENT DOCKETING, ONE CENTURY TOWER, P.O. BOX 1832, NEW HAVEN, CT, 06508-1832, US

(21) Appl. No.: 12/381,288

(22) Filed: Mar. 10, 2009

Related U.S. Application Data
(60) Provisional application No. 61/069,090, filed on Mar. 12, 2008.

(51) Int. Cl. G03F 7/004

(52) U.S. Cl. 430/280.1

(57) ABSTRACT

This invention relates to the need to improve the corrosion resistance of very low total chlorine epoxy resins which contain very low contents of organically bound chlorine. The invention relates to the improvement of corrosion resistance of such epoxy resins for electronic applications by the addition of specific additives acceptable to the electronics industry. The use of these low chlorine resins in combination with said additives has been shown to be corrosion-free on highly corrosive surfaces such as aluminum and copper, which are frequently encountered in electronic applications.

### CROSS-REFERENCE TO RELATED APPLICATIONS

This application claims the benefit of U.S. Provisional Patent Application Ser. No. 61/069,090 filed Mar. 12, 2008.

### BACKGROUND OF THE INVENTION

1. Field of the Invention

The present invention is directed to low chlorine epoxy resin formulations having improved corrosion resistance.

2. Brief Description of the Related Art

Epoxy resins have a broad range of applications within electronics and electrical engineering. They are used for molding compounds, glob top materials, printed circuit board materials, resist materials, adhesives, underfillers, and films and for shielding semiconductor, electronic and optoelectronic components. Glycidyl and polyglycidyl ether resins frequently serve as the base materials for these applications. As a general rule, these are produced by reacting respective phenols, bisphenols, polyphenols or novolak resins with epichlorohydrin.

The majority of technically available resins are obtained by the conversion of the polyphenols with epichlorohydrin. It is well known that the glycidyl ether compounds prepared by means of epichlorohydrin, especially those prepared industrially, are always contaminated with chlorine, which is present in the epoxy resins as ionic chloride, as hydrolysable chlorine (1,2-chlorohydrin) and non-hydrolyzable chlorine (alkyl chlorides). These resins typically have residual chlorine contents in excess of 1000 ppm. The residual chlorine can, particularly at the high temperature conditions which exist in current high-performance electronic systems, corrode metal parts of the underlying electronic components and will eventually cause failure of the part. While chlorine-free epoxy resins are preferable for various reasons, they appear to be manufacturable, if at all, only with a large capital outlay and thus at high cost.

Higher requirements with respect to the purity are continually being imposed on epoxy resins, especially those which are used for the production of electrical and electronic components, in order to reduce the corrosion influence of the residual chlorine content on device components, in particular contact metals such as copper and aluminum. Epoxy resins of this sort are required in particular for cationic hardening. In addition, given other hardening mechanisms, they can also replace chlorine-containing polyepoxies, which are currently an essential component of molding compounds and circuit board materials.

The ionically bound chloride produced during epoxy resin synthesis can be removed to low ppm levels by means of aqueous washing processes. The content of ionic chloride can be reduced to less than 0.0001% (1 ppm) by weight using the sometimes extravagant aqueous washing techniques. In contrast, organic compounds containing chlorine which develop as byproducts and which cause the epoxy materials to have a total chlorine content of up to 0.5% (5000 ppm) by weight are not removed by means of aqueous washing processing. Aqueous alkali treatments have been shown to reduce the hydrolysable chlorine content to as low as 0.0028% (28 ppm) by weight, but more typically 100 to 300 ppm. See, for example, U.S. Pat. No. 4,668,807 to Darbellay et al. The total organic chlorine content, which includes even less hydrolyzable chlorine, is higher yet.

Processes to reduce the total chlorine content using crystallization of diglycidyl ethers from organic solvent solutions such as isopropyl alcohol have been known for some time, and have reduced the total chlorine contents to 300 to 500 ppm. See, for example, U.S. Pat. No. 5,098,965 to Bauer et al. However, these levels have still been inadequate to protect against the corrosion of sensitive parts. Epoxy resin such as bisphenol A diglycidyl ether or bisphenol F diglycidyl ether with a total chlorine content of less than 100 ppm have until recently unknown. Epoxy novolak resins with such low total chlorine contents are still unknown. Glycidyl ether resins containing less than 100 ppm total chlorine content have now been reported by Gröppel (WO 03/072627 A1, EP 1 478 674 B1 and US Patent Application Publication 2005/0222381 A1) and have been reported to produce electronic components with reduced susceptibility to corrosion. Test boards coated with several low total chlorine resins were subjected to 100 volts DC in an 85° C., 85% relative humidity climate for 1000 hours and were reported to show no visible signs of corrosion and no significant changes in the insulation resistance could be determined. Total chlorine levels less than 100 ppm were reported to be required to produce such low levels of corrosion.

The present inventors attempted to use such low total chlorine epoxy resins to produce both liquid and dry film photoimagable resist compositions for use in MEMS and wafer level packaging applications and have found that even these formulations needed additional improvements to achieve the highest possible corrosion resistance on fine copper and aluminum structures with geometries as small as 2 to 5 μm. In choosing these additional improvements one must also be cognizant that they also need to be acceptable for semiconductor and CMOS fabrication processes. The present invention is believed to be an solution to these problems.

### SUMMARY OF THE INVENTION

In one aspect, the present invention is directed to a low chlorine photoresist formulation, comprising:

from about 2-90 wt % of an epoxy resin;

from about 0.25-10 wt % of a photoacid generator;

from about 2-100 ppm of a barium, calcium, or zinc organometallic compound; and

from about 10-98 wt % of a solvent;

wherein said formulation has a total free chlorine content of 300 ppm or less; and wherein the weight percents of said epoxy resin, photoacid generator and organometallic compound are based on the total solids weight, and wherein the weight percent of said solvent is based on the total weight of said formulation

In another aspect, the present invention is directed to products, including dry film products, made from the low chlorine photoresist formulation above.

In another aspect, the present invention is directed to a product, such as a MEMS device, a microsystem, or packaging, made from the above composition or its dry film.

### DETAILED DESCRIPTION OF THE INVENTION

Recently a few bisphenol A and bisphenol F diglycidyl ether resins with total chlorine contents below 100 ppm have become available. These resins are low MW solid or semi-solid resins with poor resist forming properties, tend to be quite brittle before cure and lead, in particular, to poor dry film resist properties. The present inventors have now formulated these resins into cationically cured epoxy resist formulations using photoacid generators such as used in SU-8 resists available commercially from MicroChem Corp. (Newton, Mass.), preferentially incorporating chlorine-free modifiers to improve film forming properties, where necessary.

The present inventors have combined these resins with various chlorine-free flexibilizing agents, added photo acid generators commonly used in cationic curing of epoxy resins, and a coating solvent to produce resist products with improved film forming properties. These formulations are similar to SU-8 2000 Resist (MicroChem) and the SU-8 Flex resist formulations disclosed in U.S. Pat. No. 6,716,568 and U.S. application Ser. No. 10/945,344, where the epoxy novolak resin has been replaced by an epoxy copolymer resin of bisphenol A diglycidy ether and bisphenol A. These resist formulations were spin coated onto suitable substrates then dried or cast onto PET films, dried and made into dry film resists, which were subsequently laminated onto the suitable substrates. These films were coated onto 100-200 nm of aluminum coated onto glass substrates, exposed through a mask, post exposure baked, and developed with a suitable solvent to give a film with an array of cavities in the film, then cured at 150° C. for 30 min in air. Such structures were next subjected to a Pressure Cooker Test (PCT) at 120° C., 60-100% humidity for 96 to 112 hours. All samples on glass showed some corrosion under the testing conditions, but the films prepared using low chlorine resists were significantly superior to films prepared with low chloride, but not low chlorine resists or a thermally cured low chloride epoxy system. Films coated onto Al, Al/Cu 1% or Cu on silicon substrates performed significantly better and etching only occurred in the less effective formulations. The samples containing a flexibilizer showed excellent film characteristics and the best corrosion resistance.

Aluminum acetylacetonate is a widely used and reported gettering agent, and has been successfully used in a number of underfiller and printed circuit board materials. However, it is a highly toxic material and is also a highly mobile ion in semiconductor applications, both negative attributes for wafer level IC or CMOS applications. Calcium, barium and zinc organometallic compounds such as the acetylacetonates are less toxic and far larger molecular species. All three metallic species show very low ion mobility and barium in particular has such a low ion mobility that it is not regulated in IC or CMOS applications. With a low chloride resist formulation we evaluated the addition of 0.1% on solids of aluminum acetylacetonate (control), zinc acetylacetonate, calcium acetylacetonate and barium acetylacetonate as gettering agents. Only the aluminum acetylacetonate fully dissolved in the resist formulation, zinc acetylacetonate was almost completely dissolved, and the others left excess insoluble organometallic solid. However, aluminum and zinc acetylacetonate both inhibited the photoimaging of the compositions at the concentrations used, 1000 ppm. Lower concentrations, <100 ppm may have imaged but were not evaluated. The remaining resists were evaluated as above and the samples containing the gettering agent calcium and barium acetylacetonate gave improved corrosion resistance and were found to be superior. This work showed that the addition of gettering agents to a low chloride resist formulation, containing as low as 1 ppm of ionic chloride had slightly improved the corrosion resistance of a resist formulation, but not nearly to the degree that was seen with the low chlorine resist formulations. Thus neither the use of a low chlorine resist nor the use of gettering agents by themselves was sufficient to provide corrosion resistance to the fine aluminum films.

When 0.1% of barium acetylacetonate was added to a low chlorine resist formulation and the insoluble solid excess removed by filtration, the total barium content in the resist formulation was found to be less than 50 ppm. Surprisingly, we found that even a low total chlorine dry film resist formulation containing less than 10 ppm barium as barium acetylacetonate when laminated onto an aluminum metallized SAW filter device now successfully passed both a 96 hr, 131° C., 85% relative humidity pressure cooker test and a 85° C., 85% humidity HAST test for more than 200 hours with no detectable corrosion under microscopic investigation. A similar resist sample not containing the barium compound was found to give inferior results.

The present inventors have therefore found that epoxy resins with total chlorine contents of less than 100 ppm formulated into compositions comprising a photo acid generator commonly used in cationic curing of epoxy resins, a suitability small amount of an organometallic compound and a coating solvent produce resist products of the present invention. Various additives can be added to improve the film forming capability or physical properties of the composition, such as other low chlorine or chlorine-free resins, chlorine-free flexibilizing agents, adhesion promoters, surfactants, inhibitors, dyes, fillers, etc. The compositions can be coated by various means such as spin coating or spray coating onto various substrates such as silicon wafers and baked at 50 to 150° C. to remove the coating solvent resulting in a nearly solventless resist film covering the substrate. The compositions can also be coated and dried on a carrier film to prepare a dry film version of the composition containing little of no residual solvent. The resulting liquid or dry film products can be used as photoresist products in micro electo mechanical systems (MEMS), also called microsystems or in packaging or wafer level packaging applications.

Suitable epoxy resins comprise 2-99 percent of the final film composition, preferably 85-99 percent based on the total solids weight in the composition, and contain less than 300 ppm of total chlorine as determined by the carbitol method, preferentially less than 100 ppm. As defined herein, the phrases “low chlorine” and “low chlorine content” refers to compositions containing 300 ppm or less of total chlorine, and more preferably 100 ppm or less of total chlorine. The type of epoxy resin is insignificant as long as it provides the desired film properties and lithographic performance. The resin can also be a blend of two or more different resins selected for their particular properties, as long as all resin components exhibit very low total chlorine contents. Acceptable resins or resin blends must be capable by themselves of forming films which are not too sticky nor too brittle and can be acceptably formulated into the present formulations or can be modified with suitable low chlorine (as defined above) or chlorine-free flexibilizers or plasticizers to give the desired film forming properties. The photoacid generator is typically a triarylsulfonium or diaryliodonim salt of a strong acid such as hexafluoroantimonate, or other perfluoronated acids or fluoromethides. Most typically a triaryl or mixed triarylsulfonium salt is employed. The amount of photoacid generator can range from approximately 0.25% of the composition to approximately 10% of the composition based on the total solids weight, but more commonly ranges between 0.25 and 5 percent. The organometallic component is typically a barium, calcium or zinc compound with at least some limited solubility in the composition and the metallic species concentration in the final film ranges from 2 to 100 ppm or more, but preferably 5 to 50 ppm. Most commonly used are the acetylacetonate complexes of these metals, but other complexing agents would work acceptably as well. Barium is the preferred metallic species.

Any suitable chlorine-free solvent or blend of solvents which can dissolve all of the components and give good film forming properties to the resist solution can be used. A wide range of solvents are acceptable, but the most commonly used are ketones, ethers and esters such a acetone, methyl ethyl ketone, 2-pentanone, 3-pentanone, cyclopentanone, cyclohexanone, 1,3-dioxolane, 2-ethoxyethyl acetate, 2-methoxylpropyl acetate, dimethoxypropane, ethyl lactate, and 2-ethoxyethylpropionate, or other unique solvents such as gamma-butyrolactone or propylene carbonate. The solvent comprises 10-98 percent by weight of the composition, typically 20-95 percent, and little to none of the dried film compositions.

A wide range of flexibilizers can be employed and can comprise 5-25 percent of the composition, preferably 5-15 percent. Suitable flexibilizers are low molecular weight glycidyl, diglycidyl or polyglycidyl ethers containing less than 300 ppm of total chlorine as determined by the carbitol method or various polyols such as caprolactone polyols. Other flexiblizers are also usable. The exact composition of the flexibilizer is unimportant as long as it is chlorine-free or contains very low total chlorine and provides the desirable film forming and lithographic properties to the film.

### EXAMPLES

The following examples are meant to illustrate, but in no way limit the present invention.

### Example 1

To a 50 gm sample of SU-8 3000 Resist [generically a mixture of an epoxidized bisphenol A novolak resin (SU-8 resin, Hexion, Houston Tex.) and other epoxy resins, a mixed triarylsulfonium hexafluoroantimonate salt (Cyracure UVI-6976, Dow Chemical) and gamma-butyrolactone as solvent], available commercially from MicroChem Corp. (Newton, Mass.), in an amber glass bottle was added 0.035 gm (0.1%) of aluminum acetylacetonate. The mixture was rolled on a roller mill under an infrared heat lamp at 40-50° C. for 2-8 hrs. The mixture was allowed to stand until cool then microfiltered at 0.2 μm.

### Example 2

To a 50 gm sample of SU-8 3000 epoxy resist in an amber glass bottle was added 0.035 gm (0.1%) of aluminum phenoxide. The mixture was rolled on a roller mill under an infrared heat lamp at 40-50° C. for 2-8 hrs. The mixture was allowed to stand and the undissolved solids filtered off by microfiltration at 0.2 μm.

### Example 3

To a 50 gm sample of SU-8 3000 epoxy resist in an amber glass bottle was added 0.035 gm (0.1%) of barium acetylacetonate. The mixture was rolled on a roller mill under an infrared heat lamp at 40-50° C. for 2-8 hrs. The mixture was allowed to stand and the undissolved solids filtered off by microfiltration at 0.2 μm.

### Example 4

To a 50 gm sample of SU-8 3000 epoxy resist in an amber glass bottle was added 0.035 gm (0.1%) of calcium acetylacetonate. The mixture was rolled on a roller mill under an infrared heat lamp at 40-50° C. for 2-8 hrs. The mixture was allowed to stand and the undissolved solids filtered off by microfiltration at 0.2 μm.

### Example 5

SU-8 3000 resist as well as the formulations produced in Examples 1 to 4 were spin coated onto 200 nm of aluminum deposited onto borosilicate glass to give approximately 50 μm coatings, then baked, UV imaged through a mask, post exposure baked for 5 min, and developed with 2-methoxypropyl acetate for 3 to 5 min to create a resist pattern on the Al coated substrates with 1 to 2 mm holes in the otherwise crosslinked SU-8 3000 resist. The imaged substrate was further cured at 150° C. for 30 minutes to provide a cured article common to the art. The glass substrates were then placed in a pressure cooker with 50 to 100 ml of DI water, sealed, then heated to 130° C. The samples were examined daily, by venting the vacuum and removing the hot parts from the pressure cooker, visually examining, quickly returning the parts and reheating for an additional time period for a total of 7 days. In the early stages of corrosion, pinholes in the aluminum were noticed and as the corrosion advanced the aluminum was totally etched away. All samples showed significant corrosion; Example 1 showed some improvement over the SU-8 3000 film and Examples 3 and 4 were slightly better again, but with obvious corrosion.

### Example 6

To a 50 gm of a mixture of an epoxidized bisphenol A novolak resin (SU-8 resin, Hexion, Houston Tex.) and other epoxy resins with a total chlorine content of approximately 800 ppm was added 0.25 gm of a proprietary tris(trifluoromethanesulfonyl)methide photoacid generator (GSID 26-1, from Ciba Inc), and 20 to 60 gm of cyclopentanone as solvent. The mixture was rolled on a roller mill under an infrared heat lamp at 40-50° C. for 6-8 hrs to dissolve all of the ingredients. The mixture was allowed to stand until cool then microfiltered.

### Example 7

In an amber glass bottle was added 42.8 gm of a proprietary copolymer of bisphenol A diglycidyl ether and bisphenol A epoxy resin containing less than 100 ppm of total chlorine content as measured by the carbitol method, 4.9 gm of Tone 305, 1.0 gm of γ-glycidoxypropyl trimethoxysilane (Z-6040 from Dow Chemical), 3.5 gm of a mixed triarylsulfonium hexafluoroantimonate (Cyracure UVI-6976), 0.01 gm of a surfactant (Baysilone 3739 from Bayer) 22.7 gm of 1,3-dioxolane and 1.8 gm of 2-pentanone. Th mixture was immediately rolled on a roller mill under a infrared heat lamp at 40-60° C. for 12-18 hrs until completely dissolved. This formulation gave a film with good coating qualities.

### Example 8

This Example was prepared in the same way as Example 7 except the Tone 305 is replaced by a proprietary polyfunctional polyol (CDR-3314 from King Industries, Norwalk, Conn.). This formulation gave a film with good coating qualities.

### Example 9

This Example was prepared in the same way as Example 8 except the Baysilone 3739 is replaced by a proprietary fluorinated surfactant (FluorN 562, from Cytonix Corp., Beltsville, Md.). This formulation gave a film with good coating qualities.

### Example 10

This Example was prepared in the same way as Example 9 except the Cyracure UVI-6976 is replaced by a proprietary tris(trifluoromethanesulfonyl)methide photoacid generator (GSID 26-1, from Ciba Inc). This formulation gave a film with good coating qualities.

### Example 11

This Example was prepared in the same way as Example 10 except the solvent mixture is replaced by propylene carbonate.

### Example 12

This Example was prepared in the same way as Example 11 except no surfactant was used.

### Example 13

To a 50 gm sample of the formulation prepared in Example 6 was added 0.035 gm (0.1%) of barium acetylacetonate. The mixture was rolled on a roller mill under an infrared heat lamp at 40-50° C. for 6-8 hrs. The mixture was allowed to stand until cool and the undissolved solids filtered off by microfiltration.

### Example 14

To a 50 gm sample of the formulation prepared in Example 7 was added 0.035 gm (0.1%) of barium acetylacetonate. The mixture was rolled on a roller mill under an infrared heat lamp at 40-50° C. for 2-8 hrs. The mixture was allowed to stand until cool and microfiltered at 0.2 μm.

### Example 15

To a 50 gm sample of the formulation prepared in Example 8 was added 0.035 gm (0.1%) of barium acetylacetonate. The mixture was rolled on a roller mill under an infrared heat lamp at 40-50° C. for 2-8 hrs. The mixture was allowed to stand until cool and the undissolved solids filtered off by microfiltration at 0.2 μm.

### Example 16

To a 50 gm sample of the formulation prepared in Example 9 was added 0.035 gm (0.1%) of barium acetylacetonate. The mixture was rolled on a roller mill under an infrared heat lamp at 40-50° C. for 2-8 hrs. The mixture was allowed to stand until cool and the undissolved solids filtered off by microfiltration at 0.2 μm.

### Example 17

To a 50 gm sample of the formulation prepared in Example 12 was added 0.035 gm (0.1%) of aluminum acetylacetonate. The mixture was rolled on a roller mill under an infrared heat lamp at 40-50° C. for 6-8 hrs. The mixture was allowed to stand until cool and the undissolved solids filtered off by microfiltration at 0.2 μm.

### Example 18

To a 50 gm sample of the formulation prepared in Example 12 was added 0.035 gm (0.1 %) of barium acetylacetonate. The mixture was rolled on a roller mill under an infrared heat lamp at 40-50° C. for 6-8 hrs. The mixture was allowed to stand until cool and the undissolved solids filtered off by microfiltration at 0.2 μm.

### Example 19

To a 50 gm sample of the formulation prepared in Example 12 was added 0.035 gm (0.1%) of calcium acetylacetonate. The mixture was rolled on a roller mill under an infrared heat lamp at 40-50° C. for 6-8 hrs. The mixture was allowed to stand until cool and the undissolved solids filtered off by microfiltration at 0.2 μm.

### Example 20

To a 50 gm sample of the formulation prepared in Example 12 was added 0.035 gm (0.1%) of zinc acetylacetonate. The mixture was rolled on a roller mill under an infrared heat lamp at 40-50° C. for 6-8 hrs. The mixture was allowed to stand until cool and the undissolved solids filtered off by microfiltration at 0.2 μm.

### Example 21

The formulations prepared in Examples 7-9 and 14-16 were coated onto PET films using a 20 or 40 μm Myers rod and dried in a hot air oven at 100° C. over to prepare dry film resist samples of each example.

### Example 22

The formluations prepared in Examples 14 and 15 were coated or laminated onto aluminum deposited glass substrates and processed as in Example 5. Both examples were found to be far superior to those materials tested in Example 5.

### Example 23

The dry film resists from Example 21 prepared from the compositions described in Examples 7 and 14-16 were laminated onto structured wafers containing 20 μm aluminum SAW filter arrays and imaged to give nominal 0.75 mm by 1.0 mm resist cavities surrounding each of the filter arrays. The wafers were then further cured at 125 to 200° C.

### Example 24

The substrate wafers prepared in Example 23 were then tested under unbiased JEDEC Standard 22-A101-B HAST conditions of 85° C., 85% relative humidity for 100 hours. The wafers prepared from films made from Examples 14-16 were found to be corrosion-free upon microscopic examination. Example 16 also passed 200 hr testing.

### Example 25

Additional SAW device wafers prepared from Example 23 dry films prepared from the compositions described in Examples 15 and 16 were further subjected to additional pressure cooker tests at 131 ° C., 100% relative humidity for 100 hrs and were also found to be corrosion-free by microscopic examination.

### Example 26

Silicon wafers with a coating of 5000 Å of Al/Cu 1% on 100 Å Ti were etched to generate nominal 10 to 50 μm line/space patterns in the Al/Cu as well as 500×500 μm square pads. The patterned metal wafers were then spin coated with SU-8 3000 Resist as described in Example 1 with a total chlorine content of approximately 1000 ppm and compositions from Examples 12 and 18 with total chlorine contents of 20-30 ppm. The wet films were dried by baking at 95° C. for 15 to 20 min resulting in uniform 25 μm thick coatings. The dried coatings were then exposed, post exposure baked and developed to generate 750×750 μm resist pads separated by 325 μm open streets. The wafers were next baked at 150° C. for 30 minutes to cure the films. The wafers were then tested under unbiased JEDEC Standard EIA/JESD22-A101-B HAST conditions of 85° C., 85% relative humidity for 1000 hours. The wafer prepared from films made from SU-8 3000 showed significant corrosion in the open areas in as little as 144 hrs whereas the wafer from Example 12 showed much reduced corrosion and the wafer from Example 18 was found to be corrosion-free upon microscopic examination for the 20 μm and larger lines and nearly corrosion-free for lines less than 10 μm after the 1000 hrs.

### Example 27

Silicon wafers with patterned coatings of 5000 Å of Al/Cu 1% on 100 Å Ti covered with imaged patterns of compositions from Examples 6, 12, and 18 were prepared as in Example 26. The wafers were then tested under unbiased JEDEC Standard JESD22-A102-C accelerated pressure cooker test (PCT) conditions of 121° C., 100% relative humidity for 98 hours. The wafer prepared from films made from Example 6 showed corrosion in the open areas in as little as 24 hrs and significant corrosion after 96 hrs. The wafer from Example 6 showed reduced corrosion and the wafers from Examples 12 and 18 were found to be nearly corrosion-free upon microscopic examination for the 15 μm and larger lines.

### Example 28

Silicon wafers with unpatterned coatings of 5000 Å of Al/Cu 1% on 100 Å Ti, 1000 Å Al with no Ti adhesion layer and 1000 Å of Cu on 100 Å Ta were covered with imaged patterns of a composition from Example 12 were prepared as in Example 26. The wafers were then tested under unbiased JEDEC Standard JESD22-A102-C accelerated pressure cooker test (PCT) conditions of 121° C., 100% relative humidity for 98 hours. All wafers showed severe corrosion in the open areas. The wafer prepared on the Al coating showed initial etching along the edges of the pads and darkening in the covered areas in 24 hrs and loss of approximately 10 μm of metal along the edges and severe darkening over the entire surface after 96 hrs. The wafer prepared on the Al/Cu coating showed reduced corrosion in the covered areas and after 96 hrs only initial attack could be seen along the edges. The wafer on the Cu coating was found to be nearly corrosion-free under the pad upon microscopic examination.

### Example 29

Silicon wafers with patterned coatings of 1000 Å Al with no Ti adhesion layer were covered with imaged patterns of compositions from Examples 6, 12, 18 and 19 were prepared as in Example 24. The wafers were then tested under unbiased JEDEC Standard JESD22-A102-C accelerated pressure cooker test (PCT) conditions of 121° C., 100% relative humidity for 48 hours. The wafer prepared from films made from Example 6 showed corrosion in the open areas. The wafer from Examples 12 showed almost no corrosion and the wafers from Examples 18 and 19 were found to be nearly corrosion-free as could be determined by the test method upon microscopic examination for the 15 μm and larger lines.

What is claimed is:

1. A low chlorine photoresist formulation, comprising:
from about 2-99 wt % of an epoxy resin;
from about 0.25-10 wt % of a photoacid generator;
from about 2-100 ppm of a barium, calcium, or zinc organometallic compound; and
from about 10-98 wt % of a solvent;
wherein said formulation has a total free chlorine content of 300 ppm or less; and
wherein the weight percents of said epoxy resin, photoacid generator and organometallic compound are based on the total solids weight, and wherein the weight percent of said solvent is based on the total weight of said formulation.

2. The low chlorine photoresist formulation of claim 1, wherein said epoxy resin comprises from 85-99 wt %, based on the solid weight of the formulation.

3. The low chlorine photoresist formulation of claim 1, wherein said photoacid generator comprises from 0.25-5 wt %, based on the solid weight of the formulation.

4. The low chlorine photoresist formulation of claim 1, wherein said photoacid generator is selected from triarylsulfonium or diaryliodonim salts of a strong acid.

5. The low chlorine photoresist formulation of claim 1, wherein said organometallic compound comprises from 5-50 ppm.

6. The low chlorine photoresist formulation of claim 1, wherein said organometallic compound is selected from barium, calcium or zinc acetylacetonate complexes.

7. The low chlorine photoresist formulation of claim 1, wherein said solvent comprises from 20-80 wt %, based on the total weight of said formulation.

8. The low chlorine photoresist formulation of claim 1, wherein said solvent is selected from the group consisting of acetone, methyl ethyl ketone, 2-pentanone, 3-pentanone, cyclopentanone, cyclohexanone, 1,3-dioxolane, 2-ethoxyethyl acetate, 2-methoxylpropyl acetate, dimethoxypropane, ethyl lactate, 2-ethoxyethylpropionate, gamma-butyrolactone, propylene carbonate, and combinations thereof.

9. The low chlorine photoresist formulation of claim 1, further comprising from about 5-25 wt % of a flexibilizer, based on the solid weight of the composition.

10. The low chlorine photoresist formulation of claim 9, wherein said flexibilizer comprises from 5-15 wt %, based on the solid weight of the formulation.

11. The low chlorine photoresist formulation of claim 9, wherein said flexibilizer is selected from the group consisting of low molecular weight glycidyl, diglycidyl or polyglycidyl ethers, caprolactone polyols, and combinations thereof, wherein said flexibilizer contains less than 300 ppm of total chlorine as determined by the carbitol method.

12. The low chlorine photoresist formulation of claim 1, further comprising additional additives selected from other low chlorine or chlorine-free resins, chlorine-free flexibilizing agents, adhesion promoters, surfactants, inhibitors, dyes, fillers, and combinations thereof.

13. The low chlorine photoresist formulation of claim 1, wherein said chlorine content is 100 ppm or less.

14. A dry film made from the low chlorine photoresist formulation of claim 1.

15. A product made from the photoresist formulation of claim 1, said product selected from a MEMS or microsystem device, or semiconductor or wafer level package.

16. A product made from the dry film of claim 14, said product selected from a MEMS or microsystem device, or semiconductor or wafer level package.
